(19) United States
(12) Patent Application Publication
(10) Pub. No.: US 2020/0212862 A1
(43) Pub. Date: Jul. 2, 2020

(54) RADIO FREQUENCY FRONT-END PROTECTION WITH TUNABLE COUPLER

(71) Applicant: QUALCOMM Incorporated, San Diego, CA (US)

(72) Inventors: Daniel HULSTEIJN, Nijmegen (NL); David Angel CALVILLO CORTES, San Diego, CA (US)

(21) Appl. No.: 16/385,844

(22) Filed: Apr. 16, 2019

Related U.S. Application Data
(60) Provisional application No. 62/785,525, filed on Dec. 27, 2018.

(51) Int. Cl. H03G 3/30; H04B 1/16; H03F 3/21; H03F 1/56

(52) U.S. Cl. CPC H03G 3/3042; H04B 1/1607; H03F 3/21; H03F 1/565; H03G 2201/103; H03F 2200/129; H03F 2200/451; H03G 2201/307; H03F 2200/387

(57) ABSTRACT

A radio frequency front-end includes a power amplifier. The radio frequency front-end also includes a coupler implemented in at least a portion of a matching circuit, the matching circuit coupled to an output of the power amplifier. The radio frequency front-end further includes a control loop comprising a first feedback terminal at an output of the power amplifier. The control loop includes the coupler coupled to the first feedback terminal of the power amplifier and is configured to generate a feedback signal provided to a second feedback terminal to adjust a gain of the power amplifier. The feedback signal is based on a reflected radio frequency signal provided by the coupler.

### CROSS-REFERENCE TO RELATED APPLICATION

The present application claims the benefit of U.S. Provisional Patent Application No. 62/785,525, filed on Dec. 27, 2018, and titled “RADIO FREQUENCY FRONT-END PROTECTION,” the disclosure of which is expressly incorporated by reference herein in its entirety.

### TECHNICAL FIELD

The present disclosure generally relates to amplifiers. More specifically, aspects of the present disclosure relate to a radio frequency front-end including a driver stage (e.g., a power amplifier module) and a control loop (e.g., a feedback protection control loop) that uses a measure of reflective power to generate a gain adjustment signal for adjusting a gain of the driver stage.

### BACKGROUND

Amplifiers are commonly used in various electronic devices, such as communications systems, to provide signal amplification. Different types of amplifiers are available for different uses. For example, a wireless communications device (e.g., a cellular phone) may include a transmitter and a receiver for bi-directional communications. The receiver may use a low noise amplifier (LNA), while the transmitter may use a power amplifier (PA). In addition, the receiver and the transmitter may use variable gain amplifiers (VGAs).

A wireless communications device includes a transmitter to support data transmission. The transmitter includes a power amplifier to amplify a radio frequency (RF) signal and provide high output power. The power amplifier may be designed to drive a particular load impedance (e.g., 50 ohms). The load impedance may vary due to various disturbances and may result in the power amplifier observing a high peak voltage, a high peak current or an unwanted combination of the high peak current and the high peak voltage. These unwanted peaks may exceed a level that can ensure reliable operation of the power amplifier. Hence, it may be desirable to detect such unwanted conditions and perform corrective actions to protect the power amplifier.

### SUMMARY

A radio frequency front-end includes a power amplifier. The radio frequency front-end also includes a coupler implemented in at least a portion of a matching circuit, the matching circuit coupled to an output of the power amplifier. The radio frequency front-end further includes a control loop comprising a first feedback terminal at an output of the power amplifier. The control loop comprises the coupler coupled to the first feedback terminal of the power amplifier and is configured to generate a feedback signal provided to a second feedback terminal to adjust a gain of the power amplifier. The feedback signal is based on a reflected radio frequency signal provided by the coupler.

A method includes receiving an input radio frequency signal at a coupler in a control loop. The method also includes measuring a reflected radio frequency signal at the coupler. The method further includes adjusting a gain of a power amplifier based on the reflected radio frequency signal.

A radio frequency front-end includes means for amplifying an input radio frequency signal. The radio frequency front-end also includes a coupler implemented in at least a portion of a matching circuit, the matching circuit coupled to an output of the amplifying means. The radio frequency front-end further includes a control loop comprising a first feedback terminal at an output of the amplifying means. The control loop includes the coupler coupled to the first feedback terminal of the amplifying means and is configured to generate a feedback signal provided to a second feedback terminal to adjust a gain of the amplifying means. The feedback signal is based on a reflected radio frequency signal provided by the coupler.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 shows a wireless device communicating with a wireless system.

FIG. 2 shows a block diagram of a wireless communications device.

FIG. 3 illustrates a block diagram of a radio frequency front-end including a driver stage and a control loop that uses a measure of reflective power to generate a gain adjustment signal for adjusting a gain of the driver stage, according to aspects of the present disclosure.

FIG. 4 illustrates a block diagram of a radio frequency front-end including a tunable standing wave detection circuit, according to one or more aspects of the present disclosure.

FIG. 5 illustrates a block diagram of a radio frequency front-end including a tunable standing wave detection circuit, according to one or more aspects of the present disclosure.

FIG. 6 illustrates a block diagram of a radio frequency front-end including a tunable standing wave detection circuit, according to one or more aspects of the present disclosure.

FIG. 7 depicts a simplified flowchart of a method of adjusting a gain of a power amplifier, according to aspects of the present disclosure.

FIG. 8 is a block diagram showing an exemplary wireless communications system in which a radio frequency front-end of the disclosure may be advantageously employed.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR” and the use of the term “or” is intended to represent an “exclusive OR”.

Power amplifiers (e.g., solid-state power amplifiers) are to be protected against reflected power at the output caused by load mismatch. Concern for these power amplifiers is heightened by customer requests for operating the power amplifiers outside of use case conditions. For example, customers may test radio frequency front-end modules including the power amplifiers outside of use case conditions where the radio frequency front-end modules are driven with high input power and are subject to high mismatch.

Some of the devices (e.g., surface-acoustic-wave (SAW) and bulk-acoustic-wave (BAW) filters) in the radio frequency front-end are particularly fragile and their performance suffers under the extreme conditions. Using devices that are more robust against extreme conditions comes at a cost of insertion loss, which directly results in reduced battery life of a wireless communications device (e.g., cellular phone). Even the power amplifiers suffer under these extreme conditions. Power amplifiers may be used that tolerate these extreme conditions. However, these high tolerance power amplifiers have reduced efficiency. Of course, the power amplifiers and the SAW and BAW filters can be protected by avoiding exposure to extreme conditions. Protecting the power amplifiers and the SAW and BAW filters by avoidance of extreme conditions reduces constraints on the devices and increases power consumption of the radio frequency front-end modules.

Some solutions for protecting the power amplifiers and filters include a ferrite-based isolator at an output of the power amplifier. The isolator redirects all reflected power to a dissipating load resistor to ensure the output of the power amplifier sees a 50 ohm load. These isolators, however, increase size and weight of a device, and have limited possibility for integration and miniaturization. Other protection implementations directed to output power control use high voltage or current detection. Thus, it would be desirable to offer more efficient protection against power reflection at the output of the power amplifier.

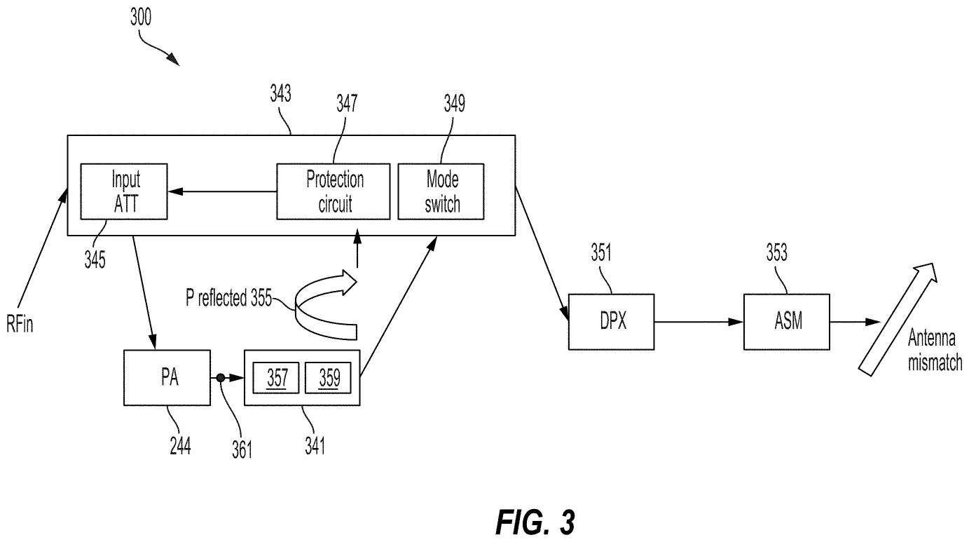

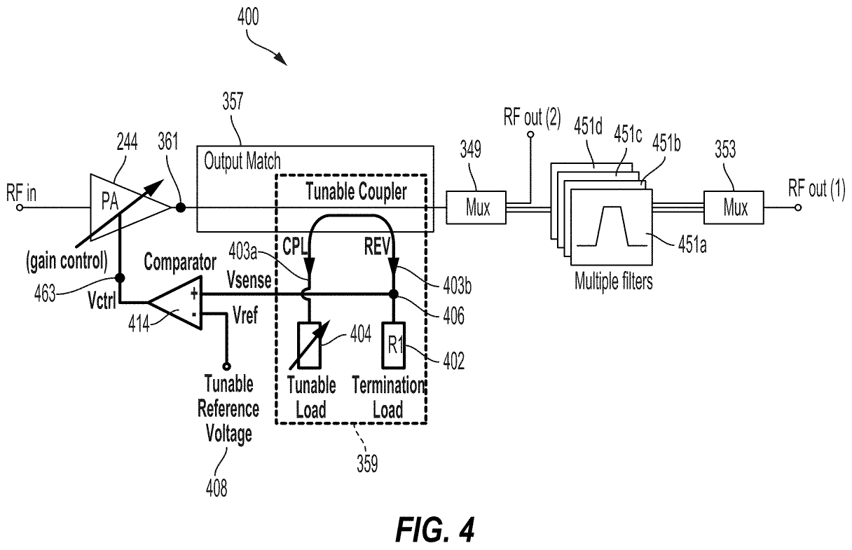

Aspects of the present are directed to a radio frequency front-end including a driver stage (e.g., a power amplifier module) and a control loop (e.g., a feedback control loop) that uses a measure of reflective power to generate a gain adjustment signal for adjusting a gain of the driver stage. In one aspect, the radio frequency front-end includes a power amplifier, a matching circuit, and a control loop. The matching circuit is coupled to an output of the power amplifier. The control loop includes a first feedback terminal (e.g., the first feedback terminal 361 of FIGS. 3 and 4) at an output of the power amplifier. The control loop further includes a coupler coupled to the first feedback terminal. The control loop is configured to generate (via the coupler) a feedback signal to a second feedback terminal (e.g., the second feedback terminal 463 of FIG. 4) to adjust a gain of the power amplifier. The feedback signal is based on a reflected radio frequency signal provided by the coupler. The coupler may be a tunable coupler that includes a tunable load. The tunable load is configured to tune to a first impedance at an output of the power amplifier based on a specified frequency band, output power and frequency for transmission. The first impedance may be a duplexer allocated for transmission in the specified frequency.

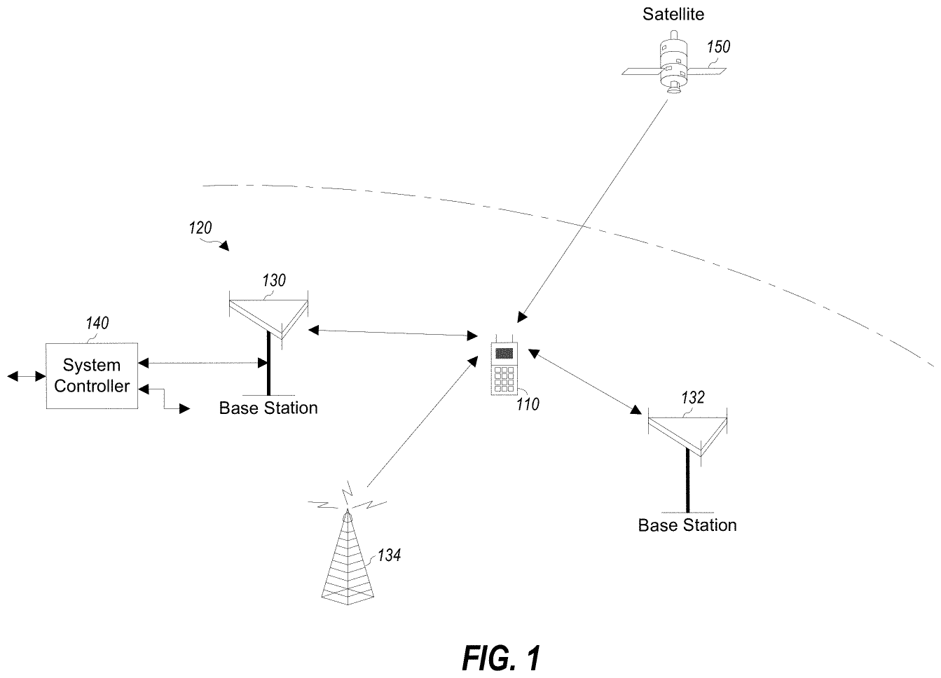

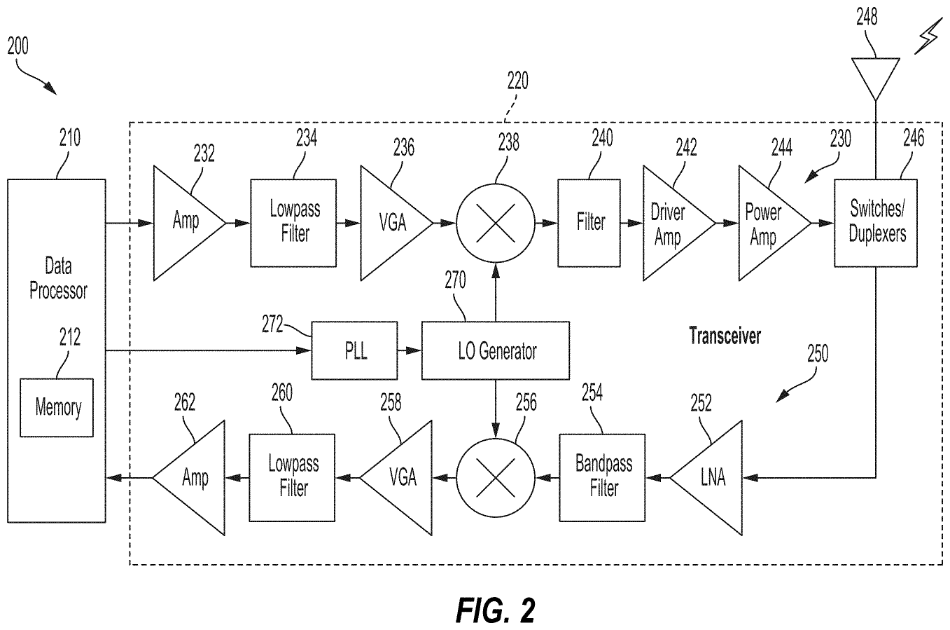

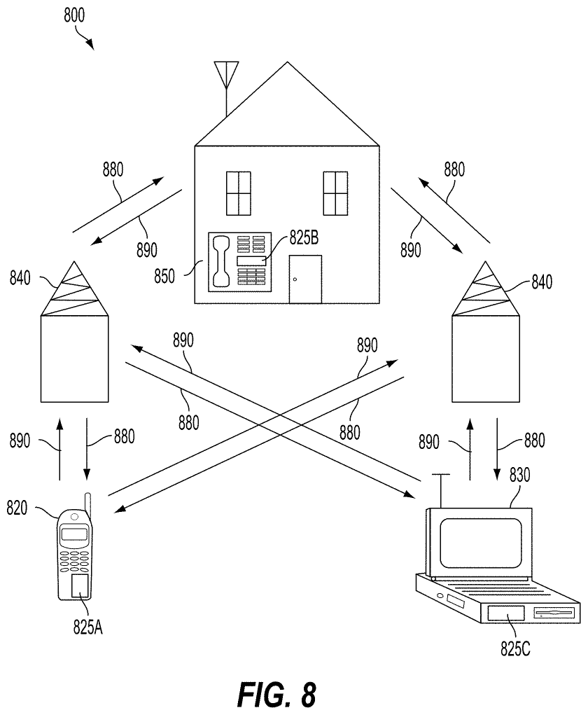

The aspects of the present disclosure may be implemented in the systems of FIGS. 1 and 8 as well as the device of FIG. 2.

FIG. 1 shows a wireless device 110 communicating with a wireless communications system 120 including the described protection circuit. The wireless communications system 120 may be a 5G system, a long term evolution (LTE) system, a code division multiple access (CDMA) system, a global system for mobile communications (GSM) system, a wireless local area network (WLAN) system, millimeter wave (mmW) technology, or some other wireless system. In a millimeter wave (mmW) system, multiple antennas are used for beamforming (e.g., in the range of 30 GHz, 60 GHz, etc.). For simplicity, FIG. 1 shows the wireless communications system 120 including two base stations 130 and 132 and one system controller 140. In general, a wireless system may include any number of base stations and any number of network entities.

A wireless device 110 may also be referred to as a user equipment (UE), a mobile station, a terminal, an access terminal, a subscriber unit, a station, etc. The wireless device 110 may be a cellular phone, a smartphone, a tablet, a wireless modem, a personal digital assistant (PDA), a handheld device, a laptop computer, a Smartbook, a netbook, a cordless phone, a wireless local loop (WLL) station, a Bluetooth device, etc. The wireless device 110 may include the protection circuit and may be capable of communicating with the wireless communications system 120. The wireless device 110 may also be capable of receiving signals from broadcast stations (e.g., a broadcast station 134), signals from satellites (e.g., a satellite 150) in one or more global navigation satellite systems (GNSS), etc. The wireless device 110 may support one or more radio technologies for wireless communications such as 5G, LTE, CDMA2000, WCDMA, TD-SCDMA, GSM, 802.11, etc.

The wireless device 110 may support carrier aggregation, which is operation on multiple carriers. Carrier aggregation may also be referred to as multi-carrier operation. According to an aspect of the present disclosure, the wireless device 110 may be able to operate in low-band from 698 to 960 megahertz (MHz), mid-band from 1475 to 2170 MHz, and/or high-band from 2300 to 2690, ultra-high band from 3400 to 3800 MHz, and long-term evolution (LTE) in LTE unlicensed bands (LTE-U/LAA) from 5150 MHz to 5950 MHz. Low-band, mid-band, high-band, ultra-high band, and LTE-U refer to five groups of bands (or band groups), with each band group including a number of frequency bands (or simply, “bands”). For example, in some systems each band may cover up to 200 MHz and may include one or more carriers. For example, each carrier may cover up to 40 MHz in LTE. Of course, the range for each of the bands is merely exemplary and not limiting, and other frequency ranges may be used. LTE Release 11 supports 35 bands, which are referred to as LTE/UMTS bands and are listed in 3GPP TS 36.101. The wireless device 110 may be configured with up to five carriers in one or two bands in LTE Release 11.

FIG. 2 shows a block diagram of an exemplary design of a wireless communications device or wireless communications device 200 that may include a protection circuit. In this exemplary design, the wireless communications device 200 includes a data processor 210 and a transceiver 220. The transceiver 220 includes a transmitter 230 and a receiver 250 that support bi-directional wireless communications. In general, the wireless communications device 200 may include any number of transmitters and any number of receivers for any number of communications systems and any number of frequency bands.

In the transmit path, the data processor 210 processes data to be transmitted and provides an analog output signal to the transmitter 230. Within the transmitter 230, the analog output signal is amplified by an amplifier (Amp) 232, filtered by a low pass filter 234 to remove images caused by digital-to-analog conversion, amplified by a VGA 236, and upconverted from baseband to radio frequency (RF) by a mixer 238. The upconverted signal is filtered by a filter 240, further amplified by a driver amplifier 242 and a power amplifier 244, routed through switches/duplexers 246, and transmitted via an antenna 248.

In the receive path, the antenna 248 receives signals from base stations and/or other transmitter stations and provides a received signal, which is routed through the switches/duplexers 246 and provided to the receiver 250. Within the receiver 250, the received signal is amplified by a low noise amplifier (LNA) 252, filtered by a bandpass filter 254, and downconverted from RF to baseband by a mixer 256. The downconverted signal is amplified by a VGA 258, filtered by a low pass filter 260, and amplified by an amplifier 262 to obtain an analog input signal, which is provided to the data processor 210.

FIG. 2 shows the transmitter 230 and the receiver 250 implementing a direct-conversion architecture, which frequency converts a signal between RF and baseband in one stage. The transmitter 230 and/or the receiver 250 may also implement a super-heterodyne architecture, which frequency converts a signal between RF and baseband in multiple stages. A local oscillator (LO) generator 270 generates and provides transmit and receive LO signals to the mixers 238 and 256, respectively. A phase locked loop (PLL) 272 receives control information from the data processor 210 and provides control signals to the LO generator 270 to generate the transmit and receive LO signals at the proper frequencies.

FIG. 2 shows an exemplary transceiver design. In general, the conditioning of the signals in the transmitter 230 and the receiver 250 may be performed by one or more stages of amplifier, filter, mixer, etc. These circuits may be arranged differently from the configuration shown in FIG. 2. Furthermore, other circuits not shown in FIG. 2 may also be used in the transmitter and the receiver. For example, matching circuits may be used to match various active circuits in FIG. 2. Some circuits in FIG. 2 may also be omitted. The transceiver 220 may be implemented on one or more analog integrated circuits (ICs), radio frequency ICs (RFICs), mixed-signal ICs, etc. For example, the amplifier 232 through the power amplifier 244 in the transmitter 230 may be implemented on an RFIC. The driver amplifier 242 and the power amplifier 244 may also be implemented on another IC external to the RFIC.

The data processor 210 may perform various functions for the wireless communications device 200, e.g., processing for transmitted and received data. A memory 212 may store program codes and data for the data processor 210. The data processor 210 may be implemented on one or more application specific integrated circuits (ASICs) and/or other ICs.

As shown in FIG. 2, a transmitter and a receiver may include various amplifiers. Each amplifier at RF may have input impedance matching and output impedance matching, which are not shown in FIG. 2 for simplicity.

For a power amplifier (e.g., gallium arsenide power amplifier) used in a wireless device, high output power as well as high power-added efficiency (PAE) are important. The power amplifier may be fabricated as an integrated circuit (IC) in order to obtain smaller size, lower cost, and other advantages. To reduce cost as well as insertion loss, the power amplifier may be coupled to an antenna without going through an isolator, which is generally used to attenuate a reflection signal due to load mismatch. As a result, a transistor in the power amplifier may observe a high peak voltage, a high peak current or an unwanted combination of the high peak current and the high peak voltage in a drain or collector of the transistor. The unwanted voltage, current or combination thereof may be higher (e.g., three to four times higher) than the power supply voltage and/or current when there is severe impedance mismatch at the output of the power amplifier. For example, the severe load mismatch may correspond to a high voltage standing wave ratio (VSWR) (e.g., VSWR of 10:1 or more).

FIG. 3 illustrates a radio frequency front-end 300 including a driver stage and a control loop that uses a measure of reflective power to generate a gain adjustment signal for adjusting a gain of the driver stage, according to aspects of the present disclosure. For illustrative purposes, some of the labelling and numbering of the devices and features of FIG. 3 are similar to those of FIG. 2. The driver stage may include a driver amplifier (e.g., the driver amplifier 242) and/or a power amplifier (e.g., the power amplifier 244). The control loop may include the drive stage, in this case the power amplifier 244, an output matching network and coupler 341, and a controller 343 (e.g., a multi-chip module (MCM) or laminated MCM).

The output matching network and coupler 341 includes an output matching network 357 and a coupler 359 (e.g., a tunable coupler). Although the output matching network 357 and the tunable coupler 359 are shown to be integrated in a single device, the output matching network 357 may be implemented in a different die that is coupled to the tunable coupler 359. The controller 343 (e.g., a complementary metal oxide semiconductor (CMOS) chip) may include an input attenuator 345, a protection circuit 347, and a mode switch 349. For example, the protection circuit 347, the mode switch 349, and the input attenuator 345 may be integrated into the controller 343. The radio frequency front-end 300 may also include multiple duplexers (e.g., filters) 351 and an antenna switch module (ASM) 353. The multiple duplexers 351 may be similar to the switches/duplexers 246, shown in FIG. 2. The antenna switch module 353 receives multiple radio frequency input signals of different frequencies from the multiple duplexers 351 and provides a single output to be transmitted by an antenna. In one aspect, the antenna switch module 353 includes multiple internal switches that combine multiple radio frequency signals from the multiple duplexers 351 into a single radio frequency output or single duplexer paths into one output at the antenna.

The input attenuator 345 receives the radio frequency input signal RFin and provides the radio frequency input signal RFin or an attenuated version of the radio frequency input signal RFin to the power amplifier 244. The power amplifier 244 amplifies the radio frequency input signal RFin and provides a radio frequency output signal to the output matching network 357 and the coupler 359. The mode switch 349 selects a specific frequency band for transmission. For example, the mode switch 349 may be a bank of switches that selects the specific path associated with a frequency band for transmission. A duplexer of the multiple duplexers 351 may be allocated for each frequency band. Thus, the mode switch selects one or more duplexers (e.g., from seven to ten duplexers), filters, or auxiliary ports for transmission of a specific frequency band. For example, the radio frequency front-end 300 may include multiple duplexers (e.g., between seven to ten duplexers) and a single power amplifier 244 and a single controller 343. The duplexers 351 may be acoustic filters.

When transmitting, the output matching network 357 and the coupler 359 provide the radio frequency output signal to at least one of the duplexers 351 or auxiliary port and the antenna switch module 353 and subsequently to the antenna (not shown) for transmission. The output matching network 357 performs output impedance matching for the power amplifier 244 and is coupled between the power amplifier 244 and the antenna. The output matching network 357 may match a low output impedance (e.g., two to four ohms) of the power amplifier 244 to a moderate impedance (e.g., 50 ohms) of the antenna.

To promote transmission efficiency, the power amplifier 244 is generally optimized for an anticipated load. When the power amplifier is presented with a load that differs from the anticipated load, a significant portion of the power output by the power amplifier 244 is reflected back to the power amplifier 244 and is not transmitted. As a result, the effective radiated power may be significantly reduced. In addition, the transmitted signal may be distorted, particularly as output power increases. An extreme condition may be reached as a result of the combination of the load mismatch and the increased output power that causes an increased reflected power. The power amplifier design and the duplexer design are adjusted to allow these extreme conditions that result in higher loss and lower PAE.

Aspects of the present disclosure are directed to preventing damage to the power amplifier 244 and the duplexers 351 of a wireless device or a base station under extreme conditions due to load mismatch. In one aspect, a tunable standing wave detection circuit (e.g., tunable voltage standing wave ratio (VSWR) detection circuit) mitigates the extreme conditions, thereby relaxing the robustness specification of the duplexer and the power amplifier. The tunable standing wave detection circuit includes the coupler 359 that receives a radio frequency signal reflected from the antenna tuning network and provides a control signal 355 representative of the reflected radio frequency signal (e.g., reflective power). The control signal 355 is fed back to the controller 343. The control signal 355 may be fed back to the protection circuit 347 of the controller 343 (e.g., the protection circuit 347 of the controller 343).

The protection circuit 347 sends a signal to the input attenuator 345 based on the output of the tunable coupler 359. A threshold may be allocated to each frequency band to ensure the input attenuator is not enabled in safe regions. For example, the threshold allocation may be implemented in part with the comparator 414 and the reference signal 408. In one aspect, the control signal 355 may be a voltage signal. The tunable coupler 359 is configured by the controller 343 to a specified frequency band corresponding to a duplexer of the multiple duplexers 351 for transmission of the radio frequency signal.

In operation, a radio frequency signal (e.g., a radio frequency input signal RFin) may traverse the radio frequency front-end 300 starting from the controller 343 to an antenna (not shown) where the signal is transmitted. For example, the input radio frequency signal first passes through the controller 343 (e.g., the input attenuator 345) then the power amplifier 244. The signal continues to passive devices of the output matching network 357 and then back to the controller 343 (e.g., the mode switch 349). A feedback terminal after the power amplifier (e.g., a first feedback terminal 361) may be part of the control loop through which the amplified radio frequency input signal RFin is provided to the feedback loop or control loop that includes the output matching network 357 and the tunable coupler 359. The feedback terminal may be in different parts of the circuit so long as the feedback terminal provides the radio frequency input signal Rfin to the control loop.

The radio frequency front-end 300 may include an antenna tuning network (not shown) to perform impedance and/or power matching for the antenna. The antenna tuning network may be referred to as a matching circuit, a tunable matching circuit or as an antenna tuning circuit. In one aspect of the disclosure, the antenna tuning network may include the output matching network 357 and/or another matching network for tuning the antenna. The controller 343 uses a measure of the reflective power to generate a gain adjustment signal for adjusting a gain of the driver stage according to aspects of the present disclosure.

FIG. 4 illustrates a block diagram of a radio frequency front-end 400 including a tunable standing wave detection circuit, according to one or more aspects of the present disclosure. For illustrative purposes, some of the labelling and numbering of the devices and features of FIG. 4 are similar to those of FIGS. 2 and 3. For example, the radio frequency front-end 400 includes the power amplifier 244, the output matching network 357, the tunable coupler 359, the mode switch 349, and the antenna switch module 353. The radio frequency front-end 400 further illustrates multiple duplexers (e.g., a first duplexer 451a, a second duplexer 451b, a third duplexer 451c, and a fourth duplexer 451d). The mode switch 349 selects one of the first duplexer 451a, the second duplexer 451b, the third duplexer 451c, and the fourth duplexer 451d for transmission of a radio frequency signal in accordance with a specific frequency band. The mode switch 349 and the antenna switch module 353 may include a multiplexer (not shown).

In one aspect, an output node associated with an output radio frequency signal RF out (1) is an auxiliary port. The auxiliary port may be connected to an external filter (e.g., a duplexer or a discrete filter or module) in a radio frequency path of a wireless device (e.g., cell phone). Thus, the radio frequency signal flow is from the power amplifier 244 to the output node associated with the radio frequency signal RF out (1). When the multiple filters are external filters, the radio frequency signal is fed into the final multiplexer or antenna switch module 353 from the external filters.

The tunable standing wave detection circuit may include the tunable coupler 359. The tunable coupler 359 includes a tunable load 404 in a first coupling path 403a, and a termination load 402 coupled to a reflected port 406 in a second coupling path 403b. The reflected port 406 is coupled to the termination load 402, which is configured to convert the reflected radio frequency signal into a control signal (e.g., the control signal 355).

The radio frequency front-end 400 further includes a comparator 414 coupled between the power amplifier 244 and the tunable coupler 359. The comparator 414 is configured to receive the control signal representative of the reflected radio frequency signal and a reference signal 408 (e.g., a tunable reference voltage). For example, the reference signal 408 represents a threshold, which if exceeded, means that the radio frequency front-end 400 is subjected to extreme conditions. For example, when the antenna switch module 353 is subject to extreme conditions at the antenna, a signal at the reflected port 406 exceeds the set reference voltage 408, and the attenuation in the attenuator 345 is increased.

The reference signal 408 may be tunable to accommodate different sensitivities (e.g., from each of the multiple duplexers), which can be predefined. The reference signal 408 may include predefined settings (per frequency band) to mitigate the issues (e.g., damage to the power amplifier 244 and the multiple duplexers) from the extreme conditions. For example, the settings of the threshold or the reference signal are characterized in a laboratory to determine which threshold values are optimum for each frequency band. These settings are then dynamically used (in real time) as part of the system. In one aspect, the control loop is an analog control loop for real time processing.

The comparator 414 outputs a mitigation signal (e.g., a gain control signal) to avoid or mitigate the extreme conditions that cause the power amplifier 244 and the duplexers 351 to be damaged. In one aspect of the disclosure, the gain control signal may be provided to the power amplifier 244 to cause the power amplifier 244 to reduce or attenuate its transmission power. For example, the gain control signal may be provided to the attenuator 345 (e.g., an analog attenuator) to attenuate the transmission power of the power amplifier or provided directly to the power amplifier 244 to adjust the transmission power. The attenuator 345 may be activated when the control signal is greater than the reference signal 408. The attenuator may reduce or cause the transmission power or an input power of the power amplifier 244 to be reduced to reduce the reflective power.

Because the input load of each of the duplexers is different, it is desirable to use a tunable coupler in the tunable standing wave detection circuit. For example, the multiple duplexers represent different loads after the mode switch 349 that the tunable coupler 359 accounts for when detecting a problem (e.g., load mismatch) at an antenna (not shown). The tunable coupler 359 accounts for the different settings by using the tunable load 404. Thus, the different loads are defined by tunable loads in the tunable coupler 359. The tunable load 404 may include a resistor-capacitor (RC) bank that is set via a digital interface with a controller (e.g., the controller 343 of FIG. 3 or a system controller). The settings may be predefined and dynamically selected based on the specified transmission frequency. For example, the settings of the tunable load 404 (resistors and capacitors) are characterized in a laboratory to determine which load values are optimum for each frequency band. These settings are then dynamically used (in real time) as part of the system.

For example, in a wireless device, systems of the wireless device send commands to the controller 343. The commands include an indication that transmission through a specified frequency band (e.g., band 1) is about to occur. In response, the controller 343 and other devices including the tunable coupler 359 tune to the specified frequency band. As part of the tuning, settings (e.g., predefined settings) for the tunable load 404 are provided to the tunable coupler 359 to prepare the tunable coupler for the transmission. The tunable standing wave detection circuit can also be used for carrier aggregation. In the case of carrier aggregation, the tunable standing wave detection circuit is directed to total power in a channel and its corresponding reflective power.

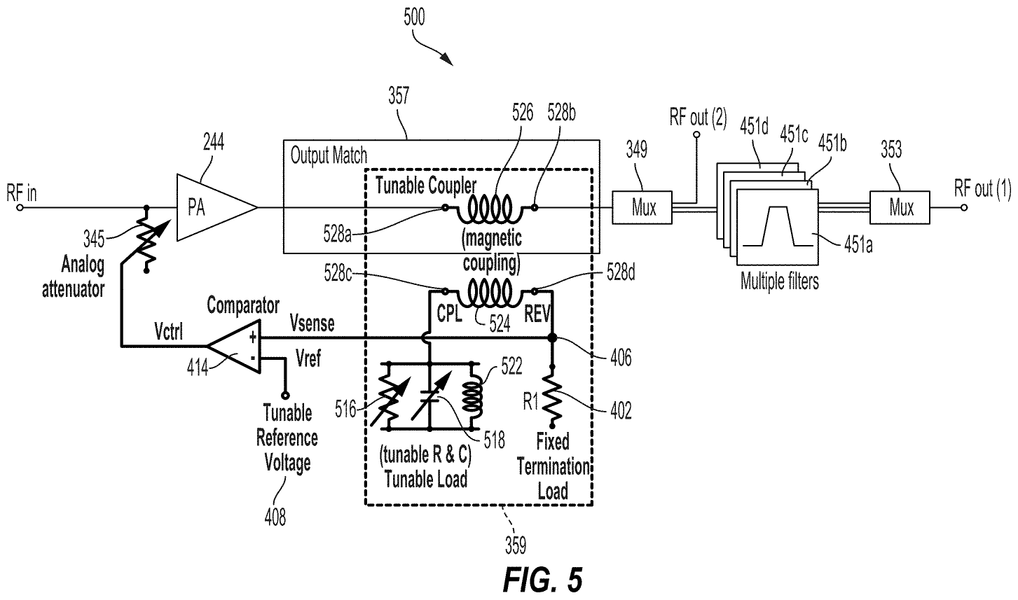

FIG. 5 illustrates a block diagram of a radio frequency front-end 500 including a tunable standing wave detection circuit, according to one or more aspects of the present disclosure. For illustrative purposes, some of the labelling and numbering of the devices and features of FIG. 5 are similar to those of FIGS. 2, 3 and 4.

The tunable coupler 359 includes two inductors (e.g., a first inductor 526 and a second inductor 524) magnetically coupled to each other. The first inductor 526 is may be part of an output matching network (e.g., a conventional output matching network). The first inductor 526 includes a first port 528a coupled to the power amplifier 244 and a second port 528b coupled to the mode switch 349.

In this aspect, the output matching network 357 shares the first inductor 526 with the tunable coupler 359 of the standing wave detection circuit. The second inductor 524 is part of the tunable coupler 359 and is independent of the output matching network 357. The second inductor 524 includes a third port 528c and a fourth port 528d. The second inductor 524 is configured to sense or measure at least a portion of the reflective power or reflected radio frequency signal flowing through the first port 528a and the second port 528b when the tunable coupler 359 is enabled.

When a system (e.g., a radio frequency front-end) is operating normally, the tunable standing wave detection circuit is ignored. For example, an output signal from the tunable coupler 359 may be ignored by increasing a threshold at the reflected port 406. Thus, when the system is operating normally, the control signal representative of the reflected radio frequency signal that is provided to the comparator 414 from the reflected port 406 is lower than the reference signal 408 and therefore the attenuator 345 is not set.

The tunable coupler 359 further includes the reflected port 406, which corresponds to the fourth port 528d of the second inductor 524. The reflected port 406 is coupled to a termination load 402 (in this case a resistor R1) configured to convert the reflected radio frequency signal into the control signal (e.g., a voltage signal). The termination load may be a fixed load (e.g., 50 ohms). For example, the 50 ohm termination is used to convert the reflected radio frequency signal into a voltage. In other aspects, the termination load 402 is not fixed. The fourth port 528d is used to sense the reflected radio frequency signal and provide the control signal, representative of the reflected radio frequency signal, to the comparator 414.

The third port 528c is for tuning the tunable coupler based on the frequency band being used for transmission. The tuning may be achieved with the tunable load 404, described with respect to FIG. 4, which includes an RC bank. For example, the RC bank includes a variable resistor 516, a variable capacitor 518, and a fixed inductor 522. The fixed inductor compensates the variable capacitor 518.

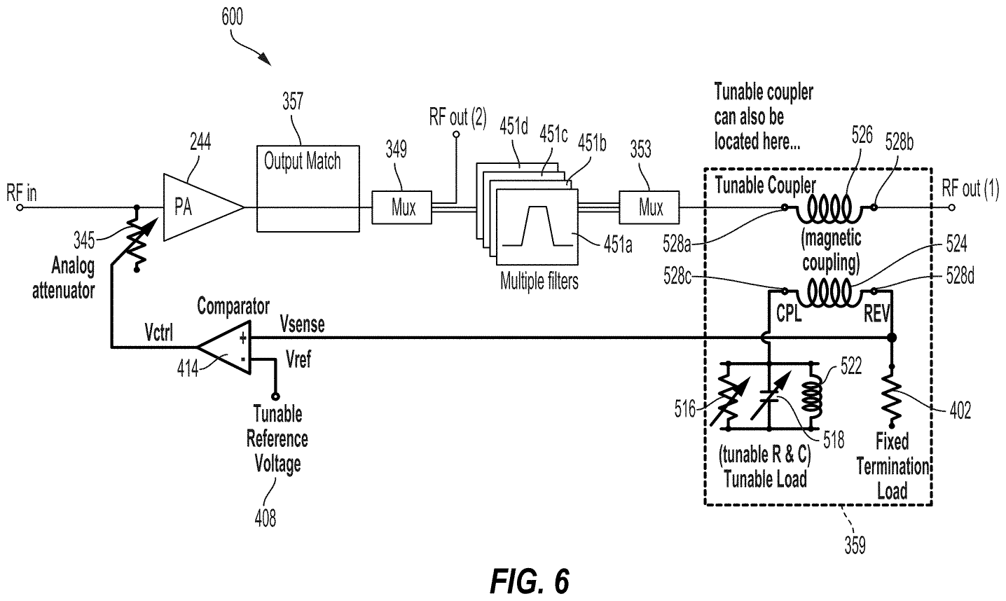

FIG. 6 illustrates a block diagram of a radio frequency front-end 600 including a tunable standing wave detection circuit, according to one or more aspects of the present disclosure. For illustrative purposes, some of the labelling and numbering of the devices and features of FIG. 6 are similar to those of FIG. 5. For example, the difference between FIG. 6 and FIG. 5 is that the tunable coupler 359 is separated from the output matching network 357 in FIG. 6. For example, the tunable coupler 359 in FIG. 6 is positioned after the antenna switch module 353 and does not share an inductor with the output matching network 357.

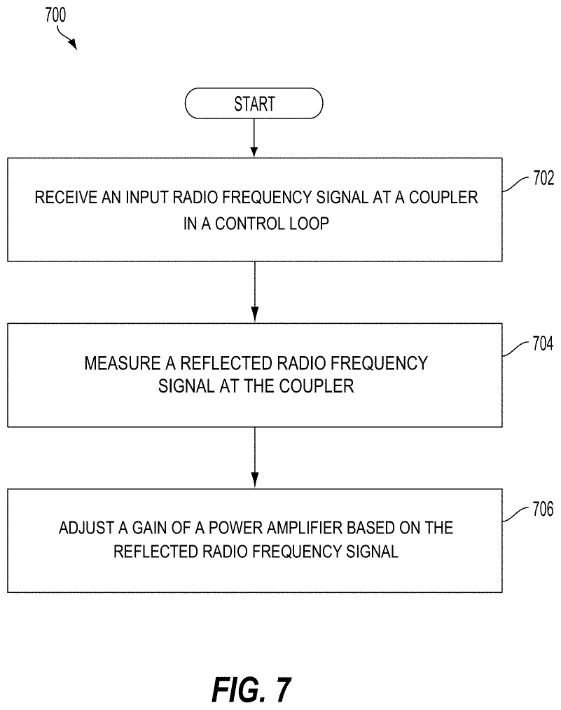

FIG. 7 depicts a simplified flowchart of a method 700 of protecting devices in a radio frequency front-end. At block 702, an input radio frequency signal is received at a coupler in a control loop. At block 704, a reflected radio frequency signal is measured at the coupler. At block 706, a gain of a power amplifier is adjusted based on the reflected radio frequency signal.

According to one aspect of the present disclosure, a protection circuit is described. The protection circuit includes means for amplifying an input radio frequency signal. The amplifying means may, for example, be the power amplifier 244 and/or the driver amplifier 242. In another aspect, the aforementioned means may be any module or any apparatus or material configured to perform the functions recited by the aforementioned means.

FIG. 8 is a block diagram showing an exemplary wireless communications system 800 in which a tunable standing wave detection circuit of the disclosure may be advantageously employed. For purposes of illustration, FIG. 8 shows three remote units 820, 830, and 850 and two base stations 840. It will be recognized that wireless communications systems may have many more remote units and base stations. Remote units 820, 830, and 850 include IC devices 825A, 825C, and 825B that include the disclosed tunable standing wave detection circuit. It will be recognized that other devices may also include the disclosed tunable standing wave detection circuit, such as the base stations, switching devices, and network equipment. FIG. 8 shows forward link signals 880 from the base station 840 to the remote units 820, 830, and 850 and reverse link signals 890 from the remote units 820, 830, and 850 to base station 840.

In FIG. 8, remote unit 820 is shown as a mobile telephone, remote unit 830 is shown as a portable computer, and remote unit 850 is shown as a fixed location remote unit in a wireless local loop system. For example, a remote units may be a mobile phone, a hand-held personal communications systems (PCS) unit, a portable data unit such as a personal digital assistant (PDA), a GPS enabled device, a navigation device, a set top box, a music player, a video player, an entertainment unit, a fixed location data unit such as a meter reading equipment, or other communications device that stores or retrieve data or computer instructions, or combinations thereof. Although FIG. 8 illustrates remote units according to the aspects of the disclosure, the disclosure is not limited to these exemplary illustrated units. Aspects of the disclosure may be suitably employed in many devices, which include the tunable standing wave detection circuit.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic device, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communications media including any medium that facilitates transfer of a computer program from one place to another. A storage media may be any available media that can be accessed by a general-purpose or special-purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD) and Blu-ray disc where disks usually reproduce data magnetically, while discs reproduce data optically with lasers. Combinations of the above should also be included within the scope of computer-readable media.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “a step for.”

1. A radio frequency front-end comprising:
a power amplifier having an output coupled to a first feedback terminal;
a coupler including a tunable load, the coupler implemented in at least a portion of a matching circuit coupled to an output of the power amplifier; and
a control loop comprising a first feedback terminal at an output of the power amplifier, the control loop comprising the coupler coupled to the first feedback terminal of the power amplifier and configured to generate a feedback signal based on a reflected radio frequency signal provided by the coupler; and
a comparator having a first input configured to receive the feedback signal, a second input coupled to a tunable reference voltage, and an output coupled a second feedback terminal, the second feedback terminal configured to adjust a gain of the power amplifier based on the feedback signal and the tunable reference voltage.

2. The radio frequency front-end of claim 1, wherein the tunable load is configured to tune to a first impedance at an output of the power amplifier based on a specified frequency for transmission.

3. The radio frequency front-end of claim 2, in which the first impedance comprises a duplexer allocated for transmission in the specified frequency.

4. The radio frequency front-end of claim 1, in which the coupler comprises:
a first port configured to receive an input radio frequency signal;
a second port configured to provide an output radio frequency signal;
a third port configured to provide a coupled radio frequency signal; and
a fourth port configured to provide the reflected radio frequency signal.

5. The radio frequency front-end of claim 4, wherein the tunable load is coupled to the third port and a termination load is coupled to the fourth port.

6. The radio frequency front-end of claim 5, in which the termination load is fixed.

7. The radio frequency front-end of claim 1, in which the coupler comprises a first inductor and a second inductor, the first inductor magnetically coupled to the second inductor.

8. (canceled)

9. The radio frequency front-end of claim 1, further comprising an attenuator coupled between an output of the coupler and the second feedback terminal.

10. The radio frequency front-end of claim 1, in which the second feedback terminal is coupled to the power amplifier or an attenuator to provide the feedback signal to cause the gain of the power amplifier to be adjusted.

11. The radio frequency front-end of claim 1, in which the matching circuit comprises an inductor shared with the coupler.

12. The radio frequency front-end of claim 1, in which the control loop comprises an analog control loop.

13. A method comprising:
receiving an input radio frequency signal at a coupler in a control loop;
tuning a tunable load of the coupler based on specified frequency band for transmitting the radio frequency signal;
measuring a reflected radio frequency signal at the coupler;
comparing the measured reflected radio signal and a tunable reference voltage to generate a gain control signal; and
adjusting a gain of a power amplifier based on the gain control signal.

14. (canceled)

15. The method of claim 13, in which adjusting the gain of the power amplifier comprises reducing an input power to the power amplifier.

16. The method of claim 13, in which adjusting the gain of the power amplifier comprises attenuating a transmission power of the power amplifier.

17. A radio frequency front-end comprising:
means for amplifying an input radio frequency signal having an output coupled to a first feedback terminal;
a coupler including a tunable load, the coupler implemented in at least a portion of a matching circuit coupled to an output of the amplifying means;
a control loop comprising a first feedback terminal at an output of the amplifying means, the control loop comprising the coupler coupled to the first feedback terminal of the amplifying means and configured to generate a feedback signal based on a reflected radio frequency signal provided by the coupler; and
a comparator having a first input configured to receive the feedback signal, a second input coupled to a tunable reference voltage, and an output coupled a second feedback terminal, the second feedback terminal configured to adjust a gain of the amplifying means, the feedback signal based on the feedback signal and the tunable reference voltage.

18. The radio frequency front-end of claim 17, wherein the tunable load is configured to tune to a first impedance at an output of the amplifying means based on a specified frequency for transmission.

19. The radio frequency front-end of claim 18, in which the first impedance comprises a duplexer allocated for transmission in the specified frequency.

20. The radio frequency front-end of claim 17, in which the coupler comprises:
a first port configured to receive the input radio frequency signal;
a second port configured to provide an output radio frequency signal;
a third port configured to provide a coupled radio frequency signal; and
a fourth port configured to provide the reflected radio frequency signal.
